(19) United States
(12) Patent Application Publication
(10) Pub. No.: US 2025/0349516 A1
(43) Pub. Date: Nov. 13, 2025

(54) PLASMA CONTROL APPARATUS

(71) Applicant: Samsung Electronics Co., Ltd., Suwon-si (KR)

(72) Inventors: Nam Kyun KIM, Suwon-si (KR); Hyun Bae KIM, Suwon-si (KR); Woongjin CHEON, Suwon-si (KR); Minyoung HUR, Suwon-si (KR); Kyung-Sun KIM, Suwon-si (KR); Donghyeon NA, Suwon-si (KR)

(73) Assignee: Samsung Electronics Co., Ltd., Suwon-si (KR)

(21) Appl. No.: 18/978,562

(22) Filed: Dec. 12, 2024

(30) Foreign Application Priority Data
May 8, 2024 (KR) 10-2024-0060682

(51) Int. Cl. H01J 37/32

(52) U.S. Cl. CPC H01J 37/32183; H01J 37/32027; H01J 37/32128; H01J 37/32568

(57) ABSTRACT

A plasma control apparatus may include a first power source configured to generate an RF signal, a second power source configured to generate a non-sinusoidal wave signal, a third power source configured to generate a direct current signal, and a mixer configured to generate an output signal based on the RF signal, the non-sinusoidal wave signal, and the DC signal, and provide the output signal to a lower electrode inside an electrostatic chuck (ESC) of a processing chamber.

### CROSS-REFERENCE TO RELATED APPLICATION(S)

This U.S. non-provisional application claims the benefit of Korean Patent Application No. 10-2024-0060682, filed on May 8, 2024, in the Korean Intellectual Property Office, the disclosure of which is incorporated herein by reference.

### BACKGROUND

Some example embodiments relate to a plasma control apparatus, a system including the plasma control apparatus, and/or a method of operating the plasma control apparatus, etc.

Generally, semiconductor devices are manufactured by performing multiple processes, such as a thin film deposition process, an etching process, and/or a cleaning process, etc. The etching process is performed within a substrate processing apparatus (and/or a plasma processing apparatus) where a plasma reaction occurs.

With regard to a substrate (e.g., a semiconductor wafer) being processed in a processing chamber, the uniformity of plasma within the chamber has a significant impact on etching performance. With regard to the etching equipment, in order to generate plasma and form patterns on the substrate, a mixture of a high frequency power source and a low frequency power source is used. The high frequency power source generates a high frequency sinusoidal wave voltage signal, and a low-frequency power source generates and mixes (e.g., synthesizes, etc.) a low-frequency sinusoidal wave voltage signal and supplies a mixed voltage signal to a bottom part of the chamber where the substrate is placed. If a voltage with negative polarity is provided to the bottom part of the chamber, only negative voltage is applied to the surface of the substrate due to potential drop (e.g., voltage drop). In this case, positive ions may accumulate in the etched area of the substrate (in other words, the bottom surface of the pattern). Accordingly, negative ions inside the plasma may be attracted to the substrate, thereby causing defects (for example, WLC sharp defect, bending defect in straight trench structures, etc.) in which the etching direction is misaligned.

### SUMMARY

At least one example embodiment provides a method of using a radio frequency (RF) power source, a non-sinusoidal wave power source, and a direct current (DC) power source together for not only negative voltage, but also positive voltage, to be applied to the substrate, thereby reducing process defects.

At least one example embodiment also provides a method of using a RF power source and a non-sinusoidal wave power source with a specific and/or desired frequency and a DC power source that generates DC voltage together to provide a plasma control circuit that reduces and/or prevents possible interference.

According to at least one example embodiment, there is provided a plasma control apparatus including a first power source configured to generate an RF signal, a second power source configured to generate a non-sinusoidal wave signal, a third power source configured to generate a DC signal, and a mixer configured to generate an output signal based on the RF signal, the non-sinusoidal wave signal, and the DC signal, and provide the output signal to a lower electrode inside an electrostatic chuck (ESC) of a processing chamber.

Additional aspects of one or more example embodiments will be set forth in part in the description which follows and, in part, will be apparent from the description, or may be learned by practice of the inventive concepts.

According to some example embodiments, it is possible to apply not only a negative voltage but also a positive voltage to the substrate by using a RF power source, a non-sinusoidal wave power source, and a DC power source together, and thus process defects may be reduced.

According to some example embodiments, it is possible to decrease and/or prevent possible interference by using the RF power source and the non-sinusoidal wave power source with a desired frequency, and using a DC power source that generates the DC voltage.

Additional features and advantages of one or more example embodiments of the inventive concepts will be set forth in the description which follows, and in part will be apparent from the description, or may be learned by practice of the inventive concepts. The objectives and other advantages of one or more example embodiments of the inventive concepts will be realized and attained by the structure particularly pointed out in the written description and claims hereof as well as the appended drawings.

### BRIEF DESCRIPTION OF THE DRAWINGS

These and/or other aspects, features, and advantages of one or more example embodiments of the inventive concepts will become apparent and more readily appreciated from the following description of example embodiments, taken in conjunction with the accompanying drawings of which:

FIG. 1 is a block diagram illustrating a substrate processing apparatus according to at least one example embodiment;

FIG. 2 is a diagram illustrating a substrate processing apparatus according to at least one example embodiment;

FIG. 3 is a block diagram illustrating a mixer according to at least one example embodiment;

FIG. 4A is a diagram illustrating a voltage graph representing an RF signal over time according to at least one example embodiment;

FIG. 4B is a diagram illustrating a voltage graph representing a non-sinusoidal wave signal over time according to at least one example embodiment;

FIG. 4C is a diagram illustrating a voltage graph representing a DC signal over time according to at least one example embodiment;

FIG. 5A is a voltage graph measured at an ESC over time if a first synthesized signal, which is a synthesis of an RF signal and a non-sinusoidal wave signal, is applied to the ESC according to at least one example embodiment;

FIG. 5B is a voltage graph measured on the substrate over time if a first synthesized signal, which is a synthesis of an RF signal and a non-sinusoidal wave signal, is applied to the ESC according to at least one example embodiment;

FIG. 6A is a voltage graph measured at the ESC over time if a second synthesized signal composed of RF signal, a non-sinusoidal wave signal and a DC signal is applied to the ESC according to at least one example embodiment;

FIG. 6B is a voltage graph measured on the substrate over time if a second synthesized signal combining RF signal, a non-sinusoidal wave signal and a DC signal is applied to the ESC according to at least one example embodiment; and

FIGS. 7A, 7B and 7C are diagrams illustrating a circuit diagram of a mixer according to at least one example embodiment.

### DETAILED DESCRIPTION

The terms used herein are selected from currently widely used general terms when possible while considering the functions in the example embodiments. However, the terms may vary depending on the intention or precedent of a person of ordinary skill in the art, the emergence of new technology, and the like. Further, in certain cases, there are also terms selected by the applicant, and in those cases, the meaning will be described in detail in the corresponding descriptions. Therefore, the terms used for the example embodiments should be defined based on the meaning of the terms and the contents of the example embodiments, rather than the simple names of the terms.

Throughout the specification, when a part is described as “comprising or including” a component, it does not exclude another component but may further include another component unless otherwise stated. Furthermore, terms such as “ . . . unit,” “ . . . group,” and “ . . . module” described in the specification mean a unit that processes at least one function or operation, which may be implemented as hardware, software, or a combination thereof.

Hereinafter, some example embodiments of the inventive concepts will be described in detail with reference to the accompanying drawings so that those of ordinary skill in the art to which the inventive concepts pertain may easily implement them. However, the inventive concepts may be implemented in multiple different forms and is not limited to the example embodiments described herein.

Hereinafter, some example embodiments will be described in detail with reference to the drawings.

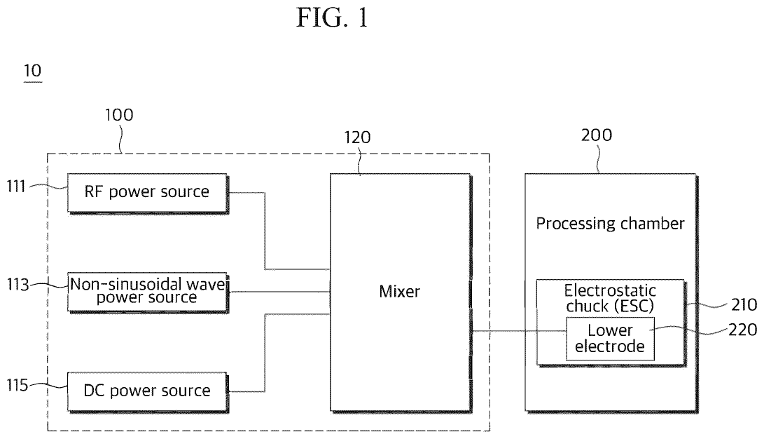

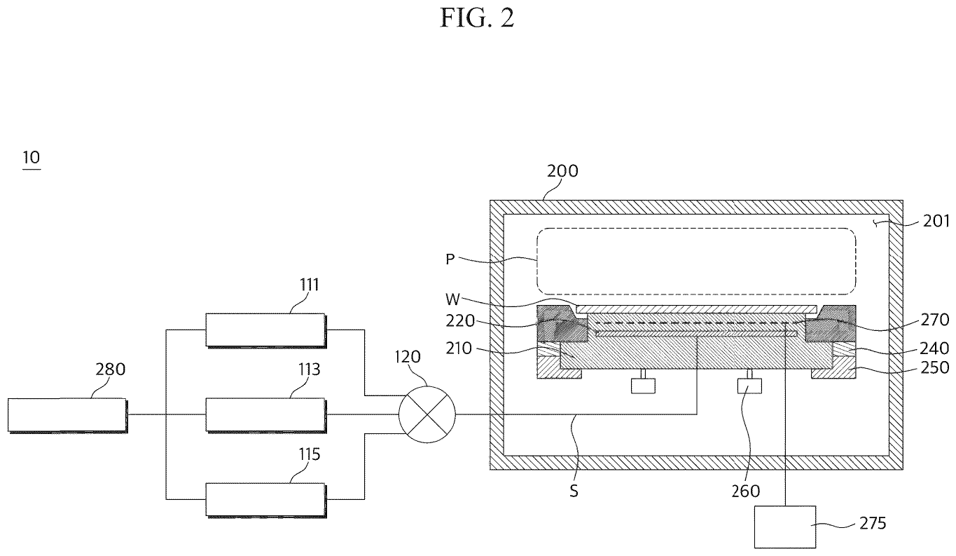

FIG. 1 is a block diagram illustrating a substrate processing apparatus 10 according to at least one example embodiment. FIG. 2 is a diagram illustrating the substrate processing apparatus 10 according to at least one example embodiment. The substrate processing apparatus 10 may include a plasma control apparatus 100 and/or a processing chamber 200, but the example embodiments are not limited thereto, and for example, the substrate processing apparatus 10 may include a greater or lesser number of constituent components. The substrate processing apparatus 10 is a device for processing a substrate (e.g., a semiconductor wafer, etc.), and may be called a substrate processing system.

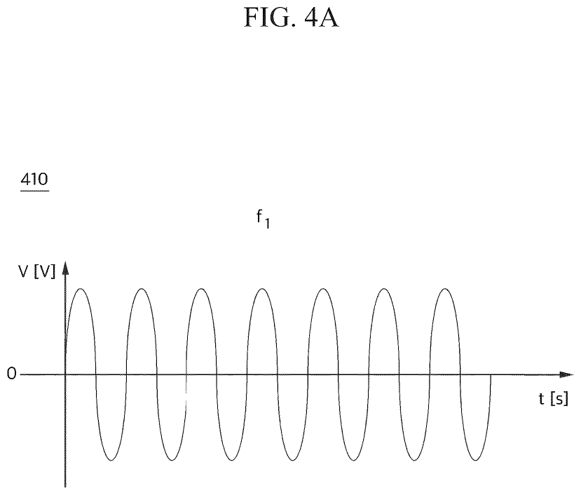

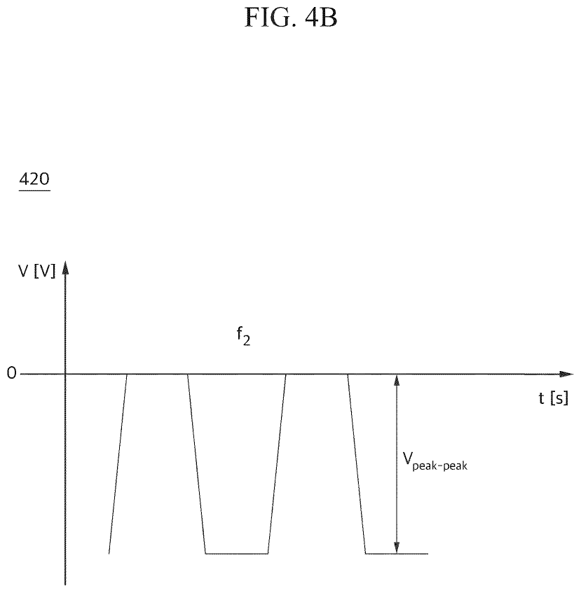

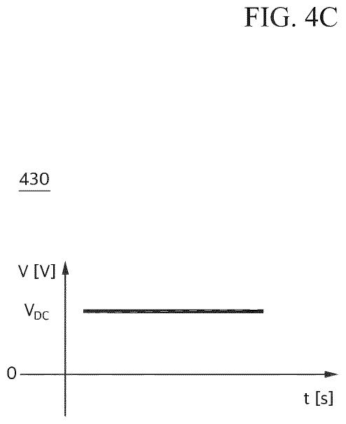

Referring to FIGS. 1 and 2, the plasma control apparatus 100 may include an RF power source 111, a non-sinusoidal wave power source 113, a DC power source 115, and/or a mixer 120, etc., but is not limited thereto. According to at least one example embodiment, the RF power source 111 is a first power source 111 that generates a RF signal, e.g., a high-frequency RF signal, etc., and may be called an RF signal generator. The RF signal will be explained in further detail in connection with FIG. 4A. FIG. 4A is a diagram illustrating a voltage graph 410 representing an RF signal over time. The RF signal is a sinusoidal wave signal and may be a voltage signal with a high frequency f₁. For example, the frequency f₁ may be 60 MHz to 100 MHz, but is not limited thereto. The RF power source 111 may be a source that supplies power (and/or the electrical energy) to the substrate processing apparatus 10 to ionize electrons within the substrate processing apparatus 10 and generate plasma. The frequencies of the RF signals described above are examples, and RF signals of various frequencies may be used. Even though it is illustrated that the plasma control apparatus 100 includes only the RF power source 111, the non-sinusoidal wave power source 113, the DC power source 115, and the mixer 120, the plasma control apparatus 100 may further include other components, such as an ESC 210, and/or a lower electrode 220 of the processing chamber 200, etc.

According to at least one example embodiment, the non-sinusoidal wave power source 113 may be the second power source 113 that generates a non-sinusoidal wave signal, which may be a low frequency signal, and the non-sinusoidal wave power source 113 may be called a non-sinusoidal generator (NSG), but the example embodiments are not limited thereto. The non-sinusoidal wave signal may be a square wave signal, but is not limited thereto. The non-sinusoidal wave signal may be a square wave signal with a low frequency pulse, etc. The non-sinusoidal wave signal will be explained with respect to FIG. 4B. FIG. 4B is a diagram illustrating a voltage graph 420 representing a non-sinusoidal wave signal over time, but the example embodiments are not limited thereto. The non-sinusoidal wave signal may be a non-sinusoidal wave signal with a low frequency f₂. For example, the low frequency f₂ may be 400 kHz, but is not limited thereto. For example, a peak to peak (Vₚₑₐₖ₋ₚₑₐₖ) value of a non-sinusoidal wave signal may be 10 kV, but is not limited thereto.

The non-sinusoidal wave signal may be the source that supplies power to the substrate processing apparatus 10 to create and/or generate a pattern on the substrate by moving positive ions within the substrate processing apparatus 10. The non-sinusoidal wave signal may be a unipolar signal corresponding to a negative or positive voltage throughout the entire section, but the example embodiments are not limited thereto. The frequency of the non-sinusoidal wave signal described above is an example, and the non-sinusoidal wave signals of various frequencies may be used.

According to at least one example embodiment, the DC power source 115 is the third power source 115 and may generate a DC signal. The DC power source 115 may be called a DC signal generator. The DC power source 115 may be a source that supplies the DC electrical energy to the substrate processing apparatus 10. The DC signal may be a unipolar signal corresponding to a positive voltage or negative voltage. If the non-sinusoidal wave signal is a unipolar signal with a voltage of the first polarity, the DC signal may be a DC signal having a voltage of a second polarity opposite to the first polarity. For example, if the non-sinusoidal wave signal is a unipolar signal with a negative voltage in all sections, the DC signal may be a DC signal with a positive voltage, etc. The DC signal will be explained with respect to FIG. 4C. FIG. 4C is a diagram illustrating a voltage graph 430 representing a DC signal over time. The DC signal may have a voltage value called V_{DC}. The voltage value V_{DC} may be a voltage value with a positive polarity (in other words, (+) potential). The voltage value V_{DC} of a DC signal may be, e.g., 10% to 20% of the peak-to-peak value of a non-sinusoidal wave signal, but is not limited thereto. For example, if the peak to peak (Vₚₑₐₖ₋ₚₑₐₖ) value of the non-sinusoidal wave signal is 10 kV, the voltage value V_{DC} of the DC power source 115 may be 1500 V, but the example embodiments are not limited thereto.

According to at least one example embodiment, the mixer 120 may refer to a circuit and/or device that obtains and/or generates one output signal from two or more types of input signals, but is not limited thereto. For example, the mixer 120 may receive an RF signal generated from the RF power source 111, a non-sinusoidal wave signal generated from the non-sinusoidal wave power source 113, and/or a DC signal generated from DC power source 115, etc., and may mix the signals. The mixer 120 may generate an output signal by mixing the RF signal, the non-sinusoidal wave signal, and/or the DC signal, etc. For example, the mixer 120 may be a triple mixer that receives three or more types of signals and mixes the waveforms of the signals, but is not limited thereto. The mixer 120 may provide an output signal to the lower electrode 220 inside the ESC 210 of the processing chamber 200, but is not limited thereto.

According to at least one example embodiment, the processing chamber 200 is at least one chamber for processing a substrate W and may be a chamber for performing an etching process on the substrate W, etc. The processing chamber 200 has at least one internal space 201, and plasma P may be formed in the internal space 201, so that a plasma treatment process may be performed on the substrate W, which is the object to be processed. The plasma treatment process may be an etching process. The processing chamber 200 may include the ESC 210 that supports the substrate W, which is the object to be processed, and the lower electrode 220 placed inside the ESC 210, etc., but is not limited thereto.

According to at least one example embodiment, the ESC 210 may be a holding mechanism (in other words, a susceptor) for maintaining (e.g., supporting, etc.) the semiconductor substrate W. The ESC 210 may be in the internal space 201 of the processing chamber 200, and the ESC 210 may be configured to fix the substrate W to the lower electrode 220 using the power of static electricity, but is not limited thereto. The ESC 210 may include an insulating member (for example, ceramic, etc.) and a conductive member (for example, an aluminum body, etc.). The insulating member may include an electrostatic electrode 270 to maintain the substrate W with electrostatic adsorption. The electrostatic electrode 270 included in the insulating member is connected to a separate DC high-voltage power supply 275 and a constant voltage is applied, and thus the substrate W may be adsorbed and maintained by the electrostatic force. The constant voltage may be a voltage of hundreds to thousands of volts, but is not limited thereto. In other words, the DC high-voltage power supply 275 is a power source that generates power applied to the electrostatic electrode 270 to generate attractive force to support, secure, and/or maintain the substrate W on the ESC 210. The DC high-voltage power supply 275 has a different (e.g., separate) configuration from the DC power source 115 of the plasma control apparatus 100 for generating power to be applied to the lower electrode 220, but the example embodiments are not limited thereto. If the DC high-voltage power supply 275 applies voltage to the ESC 210 through the electrostatic electrode 270, the substrate W supported on the ESC 210 is charged with the opposite potential, and the forces may attract each other due to the charged potential. Through this, the substrate W may be fixed, e.g., horizontally, but is not limited thereto. The substrate W may be placed on the upper part of the ESC 210. The ESC 210 may be formed in a shape and size similar to that of the substrate W, but the shape and/or size of the ESC 210 are not limited thereto.

A gas flow path for supply (not illustrated) may be formed in the ESC 210, and the gas flow path for supply (e.g., gas flow path, etc.) may be connected to a gas supply source (not illustrated) to supply gas to the interior of the processing chamber 200 and/or to the substrate, etc. The gas flow path for supply may be formed through the ESC 210 from one side (for example, a bottom part side) of the processing chamber 200, but is not limited thereto. A small space (not illustrated) where gas is temporarily stored may be formed on a surface of the upper part of the ESC 210. The small space may be arranged to overlap the substrate W, and the gas may be supplied from a gas source through the gas flow path for supply. The gas may include at least one inert gas, such as He gas, etc., and gas used in plasma processing may also be used. The gas may be a gas for maintaining the temperature of the substrate W by facilitating heat transfer between the substrate W and the ESC 210 while the plasma treatment process is in progress. In other words, to precisely control the temperature of the substrate W, a cooling gas such as He gas may be supplied to the small space between the ESC 210 and the substrate W through a gas flow path H for supply, but the example embodiments are not limited thereto.

According to at least one example embodiment, the lower electrode 220 is an electrode in the internal space of the processing chamber 200 and may be placed in the bottom part of the processing chamber 200. Specifically, the lower electrode 220 may be placed inside the ESC 210, but is not limited thereto. Signals supplied from the first power source 111, the second power source 113, and/or the third power source 115 may be applied to the lower electrode 220 through the mixer 120, but is not limited thereto. The lower electrode 220 may be provided in the form of a disk. The shape of the lower electrode 220 described above is a mere example and is not limited thereto. The shape of the lower electrode 220 may include a plate, a wire screen, an arbitrary distributed arrangement, a sheet type, and/or a mesh type electrode, etc.

The lower electrode 220 and an upper electrode (not illustrated) may be placed in the internal space of the processing chamber 200. The lower electrode 220 may be a parallel plate-type electrode paired with the upper electrode, but is not limited thereto. The lower electrode 220 may be placed in the bottom part of the processing chamber 200. The upper electrode may be placed in the upper part of the processing chamber 200 to face the lower electrode 220. The upper electrode may be at a certain and/or desired distance from the lower electrode 220. Power may also be applied to the upper electrode. An electromagnetic field is formed in the space between both electrodes, and the reaction gas supplied to this space may be excited into a plasma state. The plasma treatment process may be performed using the above-described plasma P. Description of the configuration of the upper part area (for example, an upper electrode) of the processing chamber 200 is omitted. However, in at least one example embodiment, general elements of a substrate processing apparatus may be included in the substrate processing apparatus 10.

According to at least one example embodiment, the processing chamber 200 of the substrate processing apparatus 10 may further include a driving part 260, a focus ring 230, an edge electrode 240, and/or an insulating ring 250, etc. The focus ring 230 may be arranged to surround the outer circumference of the substrate W placed on the ESC 210, but is not limited thereto. The focus ring 230 may be on the upper part of the insulating ring 250 around the ESC 210, but is not limited thereto. For example, the focus ring 230 may be implemented in a ring shape to surround the substrate W, etc. For convenience of explanation, it is illustrated that the edge electrode 240 is on the upper part of the insulating ring 250. However, the example embodiments are not limited thereto, and for example, the edge electrode 240 may be placed inside the insulating ring 250, etc. The edge electrode 240 may be implemented in a ring shape, but is not limited thereto, and may be implemented in other shapes. The ESC 210 may be installed to move up and down by the driving part 260.

According to at least one example embodiment, the substrate processing apparatus 10 may further include a reaction gas source (not illustrated) that supplies reaction gas to generate plasma P and/or a reaction gas flow path for supply (not illustrated), but is not limited thereto. After the reaction gas is supplied into the processing chamber 200, by applying power to the lower electrode 220 and the upper electrode, the reaction gas may be activated, and the plasma P may be generated.

According to at least one example embodiment, the substrate processing apparatus 10 may further include at least one processor 280 (e.g., processing circuitry, etc.). The processor 280 may control the first power source 111, the second power source 113, and/or the third power source 115, etc., but is not limited thereto. The processor 280 may determine whether to activate the first power source 111, the second power source 113, and/or the third power source 115, and/or may control the frequency and/or peak-to-peak voltage value of the RF signal, etc. Additionally, the processor 280 may control the frequency and/or peak-to-peak voltage value of the non-sinusoidal wave signal. The processor 280 may also control the voltage value of the DC signal.

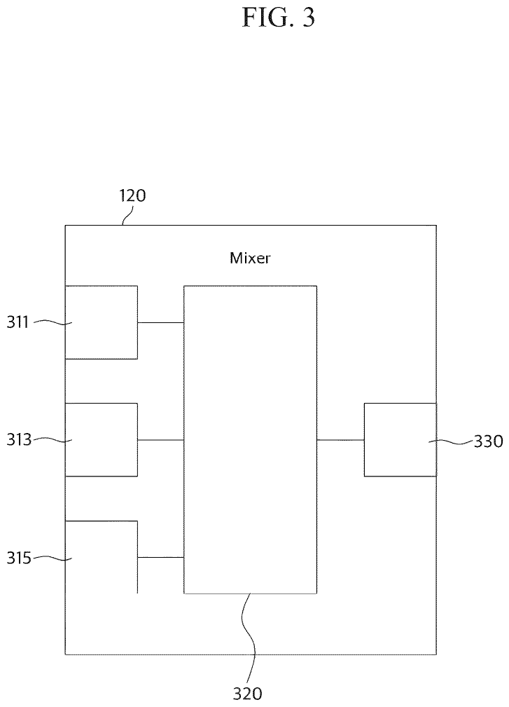

FIG. 3 is a block diagram illustrating the mixer 120 according to at least one example embodiment.

Referring to FIG. 3, the mixer 120 may include a plurality of input ports, e.g., a first input port 311, a second input port 313, a third input port 315, etc., a mixing circuit 320, and/or at least one output port 330, etc., but is not limited thereto. The first input port 311 may receive RF signals from the first power source 111. The second input port 313 may receive non-sinusoidal wave signal from the second power source 113. The third input port 315 may receive the DC signal from the third power source 115. According to some example embodiments, the mixer 120, the first input port 311, the second input port 313, the third input port 315, and/or the mixing circuit 320, etc., may be implemented as processing circuitry. The processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The mixing circuit 320 may be a circuit to reduce and/or prevent signals received through the plurality of input ports, e.g., the first input port 311, the second input port 313, and/or the third input port 315, etc., from interfering with each other. The mixing circuit 320 may generate an output signal by mixing an RF signal, a non-sinusoidal wave signal, and/or a DC signal, etc. The mixing circuit 320 may further include a generally known mixer circuit for synthesizing waveforms of signals. For example, the mixing circuit 320 is a circuit for combining (+) multiple signals, and may further include a passive mixer circuit and/or an active mixer circuit. The output port 330 may output an output signal generated from the mixing circuit 320. The output signal that is output from the output port 330 of the mixer 120 may be applied to the lower electrode 220 inside the ESC 210 of the processing chamber 200, but is not limited thereto.

If mixing various types of signals, the mixing circuit 320 of the mixer 120 may include filters and/or capacitors to reduce and/or prevent the input signals from influencing each other. Further, the mixing circuit 320 may include an impedance matching circuit for impedance matching. The various elements of the mixing circuit 320 will be explained later.

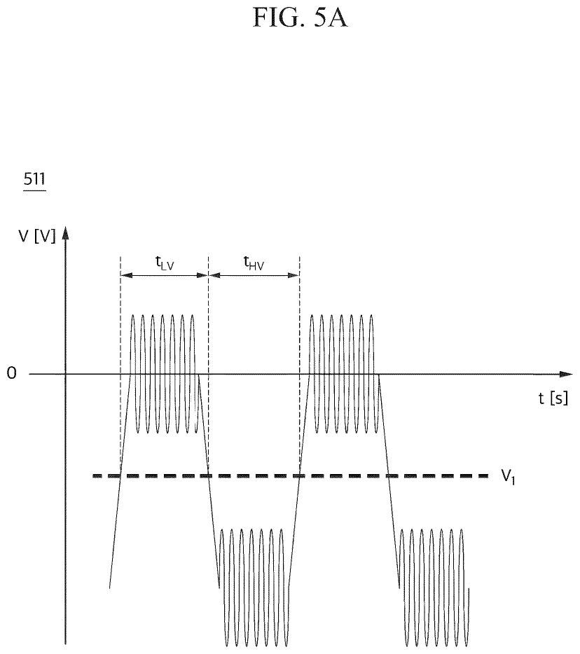

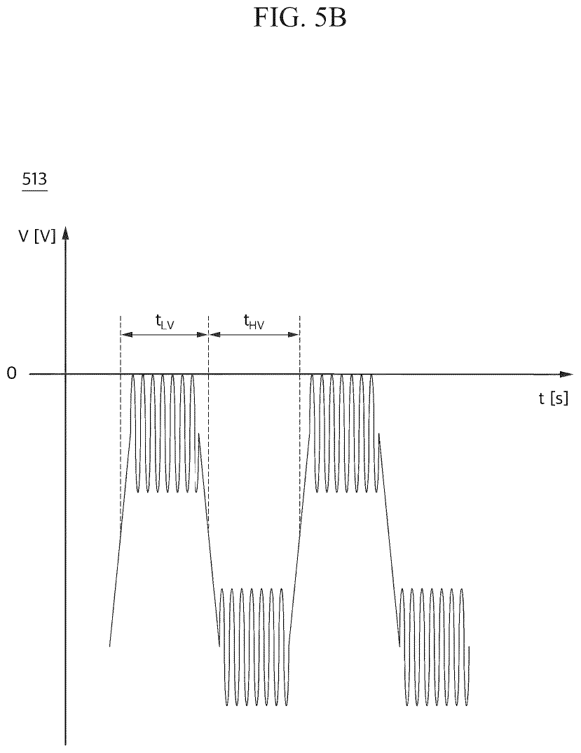

FIG. 5A is a voltage graph 511 measured on the ESC 210 over time if a first synthesized signal in which an RF signal and a non-sinusoidal wave signal are synthesized is applied to the ESC 210. FIG. 5B is a voltage group 513 measured on the substrate over time if a first synthesized signal in which an RF signal and a non-sinusoidal wave signal are synthesized is applied to the ESC 210.

Referring to FIG. 5A, the first synthesized signal may be injected (and/or transmitted, provided, etc.) into the lower electrode 220 of the ESC 210. An intermediate voltage value V₁ of the first synthesized signal applied to the ESC 210 may be a negative value, but is not limited thereto. In a first time period t_{LV}, if a relatively small voltage is applied, depending on the waveform of the first synthesized signal, a positive voltage and a negative voltage may be applied to the ESC 210. In a second time period t_{HV}, if a relatively large voltage is applied, only a negative voltage may be applied to the ESC 210.

Referring to FIG. 5B, depending on the first synthesized signal applied to the ESC 210, the voltage signal applied to the substrate placed on a surface of the upper part of the ESC 210 may be a unipolar signal (e.g., a signal having a signal polarity, a signal having only a positive voltage or only a negative voltage, etc.). In other words, the voltage signal applied to the substrate may be a negative voltage for both the first time period t_{LV} and the second time period t_{HV}. Therefore, if the first synthesized signal is applied to the lower electrode 220 of the ESC 210, only negative voltage is applied to the substrate.

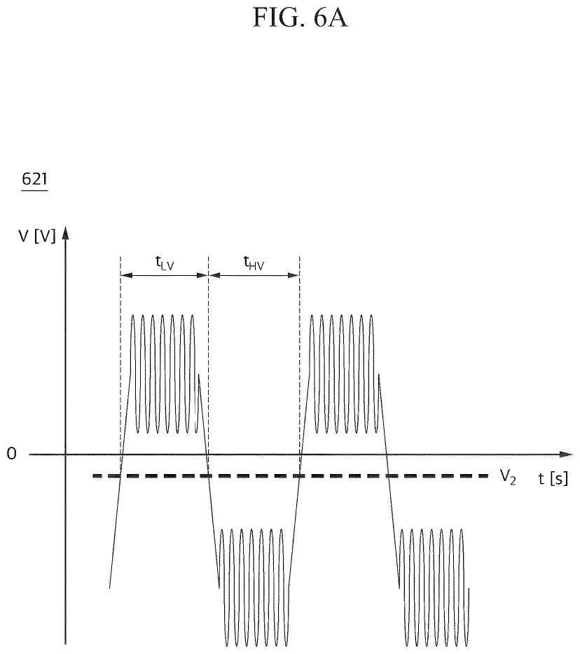

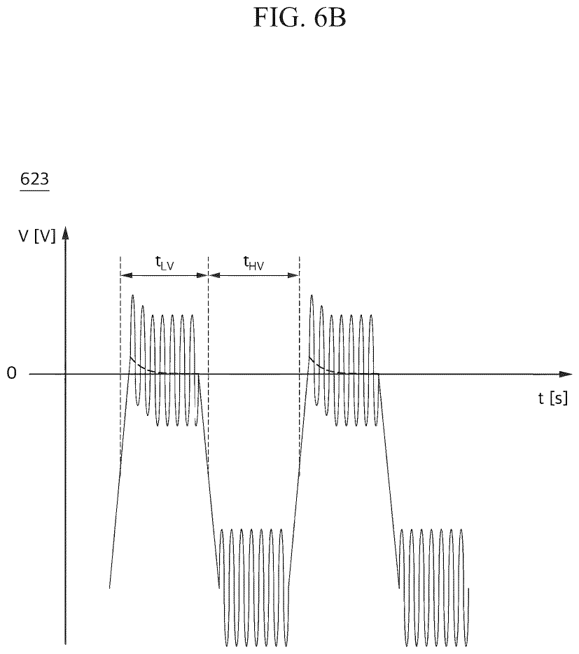

FIG. 6A is a voltage graph 621 measured by the ESC 210 over time if a second synthesized signal in which the RF signal, the non-sinusoidal wave signal, and the DC signal are synthesized is applied to the ESC 210. FIG. 6B is a voltage graph 623 measured on the substrate over time if a second synthesized signal in which the RF signal, the non-sinusoidal wave signal, and the DC signal are synthesized is applied to the ESC 210. The second synthesized signal may be a signal obtained by additionally synthesizing a DC signal with a voltage value V_{DC} with positive polarity in the first synthesized signal described in FIG. 5A.

Referring to FIG. 6A, the second synthesized signal may be injected (and/or transmitted, provided, etc.) into the lower electrode 220 of the ESC 210. An intermediate voltage value V₂ of the second synthesized signal applied to the ESC 210 may be a value as large as the intermediate voltage value V₁ of the first synthesized signal to the voltage value V_{DC} of the DC signal, but is not limited thereto. In the first time period t_{LV}, if a relatively small voltage is applied, depending on the waveform of the first synthesized signal, only positive voltage may be applied to the ESC 210. In the second time period t_{HV} if a relatively large voltage is applied, only negative voltage may be applied to the ESC 210.

Referring to FIG. 6B, according to the second synthesized signal applied to the ESC 210, a voltage signal applied to the substrate placed on the surface of the upper part of the ESC 210 may be a bipolar signal (e.g., a signal having two polarities, a signal having both positive and negative voltages, etc.). In the first time period t_{LV}, both positive and negative voltages may be applied to the substrate. In the second time period t_{HV}, the negative voltage may be applied. In other words, by adding a DC signal, the voltage level applied to the substrate may be shifted in the positive direction. Therefore, if the second synthesized signal is applied to the lower electrode 220 of the ESC 210, not only is a negative voltage applied to the substrate, but also a positive voltage may be applied to the substrate. In other words, due to the positive voltage applied in the first time period t_{LV}, cations accumulated on the bottom surface of the substrate pattern may be removed. Therefore, defects on the substrate and/or integrated circuits formed on the substrate may be removed and/or resolved by synthesizing a DC signal with a positive polarity in addition to the RF signal and a unipolar non-sinusoidal wave signal with a negative polarity, and applying the synthesized signal to the lower electrode 220.

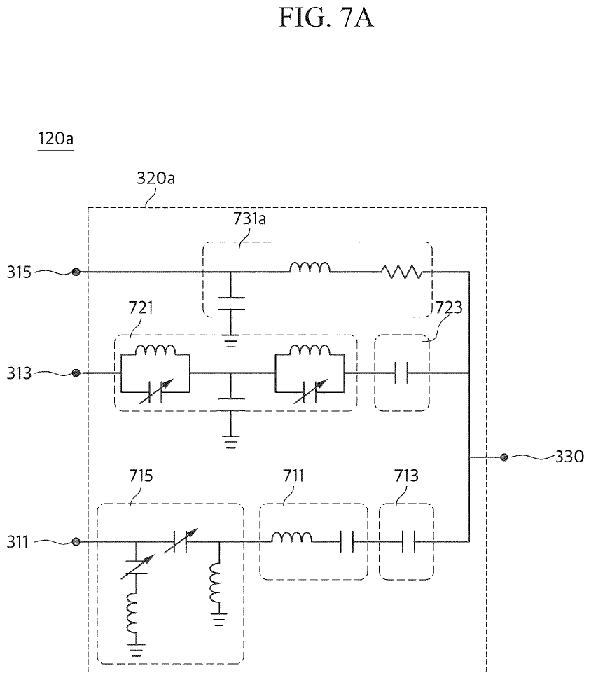

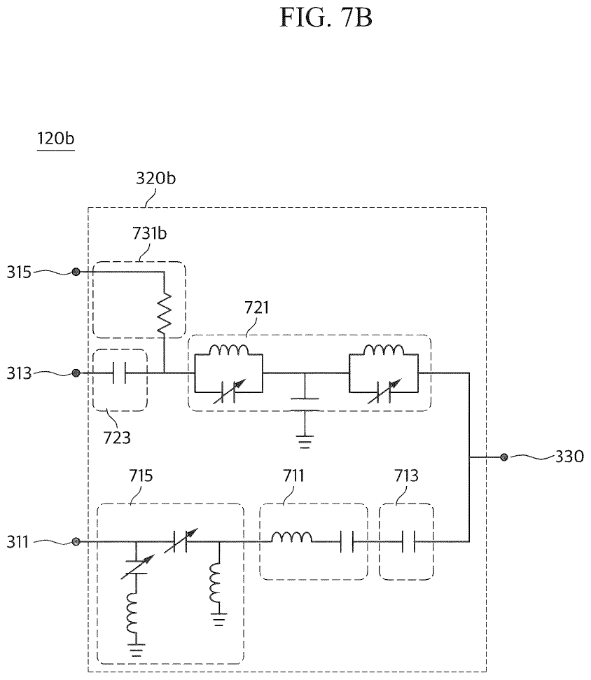

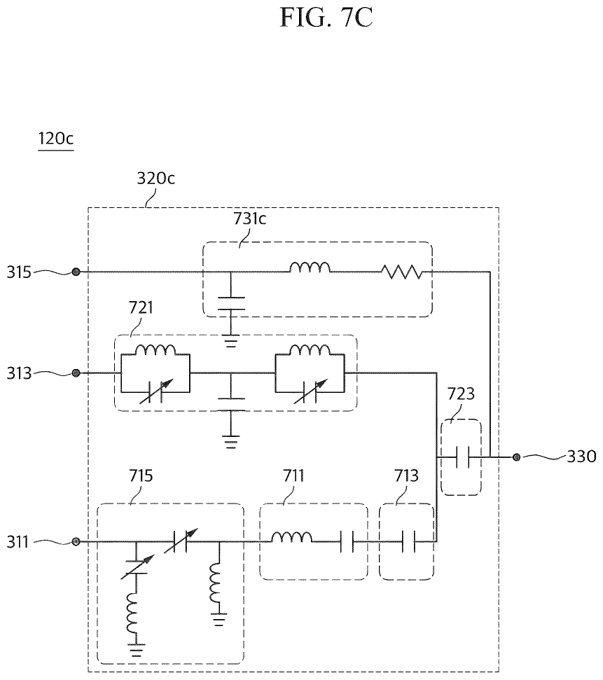

FIGS. 7A, 7B and 7C are diagrams illustrating a circuit diagram of the mixer 120 according to at least one example embodiment.

FIG. 7A is a diagram illustrating a mixing circuit 320a of a mixer 120a according to at least one example embodiment. Referring to FIG. 7A, the mixing circuit 320 of the mixer 120 is connected to a plurality of input ports, e.g., the first input port 311, the second input port 313, and/or the third input port 315, etc., and may receive various voltage signals. For example, the first input port 311 may receive RF signals from the first power source 111, and provide the received RF signals to the mixing circuit 320. The second input port 313 may receive the non-sinusoidal wave signal from the second power source 113, and provide the received non-sinusoidal wave signal to the mixing circuit 320. The third input port 315 may receive the DC signal from the third power source 115, and provide the received DC signal to the mixing circuit 320. In other words, the RF signal, the non-sinusoidal wave signal, and/or the DC signal may be input independently and in parallel to the first input port 311, the second input port 313, and the third input port 315 of the mixer 120, respectively, but the example embodiments are not limited thereto, and for example, two or more of the signals may be input serially to the mixer 120, etc. The first input port 311 may be called an RF signal connection part, the second input port 313 may be called a non-sinusoidal wave signal connection part, and the third input port 315 may be called the DC connection part (or a DC signal connection part).

According to at least one example embodiment, the mixer 120 may include a first filter 711 that is connected in series with the first power source 111, and the first filter 711 may reduce and/or prevent RF signals from being interfered with by non-sinusoidal wave signals, and a first capacitor 713 that is connected in series with the first power source 111 and the first capacitor 713 may reduce and/or prevent RF signals from being interfered with by DC signals, but the example embodiments are not limited thereto. The mixer 120 may include an impedance matching circuit 715 connected in series with the first power source 111, but the example embodiments are not limited thereto. The impedance matching circuit 715, the first filter 711, and/or the first capacitor 713, etc., may be connected to the RF signal connection part, but are not limited thereto.

The impedance matching circuit 715 may be a circuit that matches impedance to increase and/or maximize power delivered to the lower electrode 220 of the ESC 210. The first filter 711 may be a band pass filter (BPF) that passes only the frequency of a specific band, but the example embodiments are not limited thereto. The first capacitor 713 may be a block capacitor. In other words, in order to reduce and/or prevent RF signals from being interfered with by non-sinusoidal wave signals input to the second input port 313, the first filter 711 may be connected in series to the RF signal connection part. Further, in order to reduce and/or prevent the RF signal from being interfered with by the DC signal input to the third input port 315, the first capacitor 713 may be connected in series to the RF signal connection part.

According to at least one example embodiment, the mixer 120 may include a second filter 721 that is connected in series with the second power source 113 and the second filter 721 may reduce and/or prevent the non-sinusoidal wave signals from being interfered with by the RF signals, etc. Additionally, the mixer 120 may include a second capacitor 723 that is connected in series with the second power source 113 and the second capacitor 723 may reduce and/or prevent the non-sinusoidal wave signals from being interfered with by the DC signals, etc. The second filter 721 and the second capacitor 723 may be connected to the non-sinusoidal wave signal connection part.

The second filter 721 may include a low pass filter (LPF) that passes only the low-pass part and a band stop filter (BSF) that cancels only the frequency of a specific band, but the example embodiments are not limited thereto. The second capacitor 723 may be a block capacitor. In other words, in order to reduce and/or prevent the non-sinusoidal wave signals from being interfered with by the RF signal input to the first input port 311, the second filter 721 may be connected in series to the non-sinusoidal wave signal connection part. Further, in order to reduce and/or prevent the non-sinusoidal wave signals from being interfered with by the DC signal input to the third input port 315, the second capacitor 723 may be connected in series to the non-sinusoidal wave signal connection part.

According to at least one example embodiment, the mixer 120 may include a third filter 731a that is connected in series with the third power source 115 and the third filter 731a may reduce and/or prevent the DC signals from being interfered with by the RF signals and/or the non-sinusoidal wave signals, etc. In other words, the third filter 731a may be connected to the DC connection part. The third filter 731a may be an LPF that passes only the low-pass part of the signal, but is not limited thereto. In other words, by the RF signal and the non-sinusoidal wave signal, in order to reduce and/or prevent the DC signal from being interfered with, the third filter 73 la may be connected in series to the DC connection part.

The RF signals, the non-sinusoidal wave signals, and the DC signals may be synthesized without interfering with each other through the mixing circuit 320. The mixing circuit 320 may generate an output signal by mixing an RF signal, a non-sinusoidal wave signal, and a DC signal, and may output the generated output signal to the output port 330.

FIG. 7B is a diagram illustrating a circuit diagram of a mixer 120b according to at least one example embodiment. Specifically, FIG. 7B is a circuit diagram of a mixing circuit 320b of the mixer 120b in which the DC connection part is connected to the non-sinusoidal wave signal connection part, but the example embodiments are not limited thereto. Content that overlaps with FIG. 7A will be omitted for the sake of clarity and brevity.

Referring to FIG. 7B, the mixer 120b may include the second capacitor 723 that is connected in series with the second power source 113, and the second capacitor 723 may reduce and/or prevent the non-sinusoidal wave signals from being interfered with by the DC signals. The mixer 120 may include a third filter 731b that is connected in series with the third power source 115, and the third filter 731b may reduce and/or prevent DC signals from being interfered with by the RF signals and/or the non-sinusoidal wave signals, etc. In other words, in the mixer 120 according to the at least one example embodiment, the second capacitor 723 may be connected to the non-sinusoidal wave signal connection part, and the third filter 731b may be connected to the DC connection part. The second capacitor 723 may be a block capacitor, but is not limited thereto. The third filter 731b may be an LPF that passes only the low-pass part of the signal, but is not limited thereto.

According to at least one example embodiment, the mixer 120 may include the second filter 721 that is connected to the second power source 113 and the third power source 115, and the second filter 721 may reduce and/or prevent the non-sinusoidal wave signals and/or the DC signals from being interfered with by the RF signals, etc. The second filter 721 may include an LPF that passes only the low-band part and a BSF that cancels only the frequency of a specific band, but is not limited thereto.

In other words, the mixer 120 according to the at least one example embodiment illustrated in FIG. 7B may have an equivalent circuit structure that produces the same effect as the mixer 120a according to the at least one example embodiment illustrated in FIG. 7A, but is not limited thereto.

FIG. 7C is a diagram illustrating a circuit diagram of a mixer 120c according to at least one example embodiment. Specifically, FIG. 7C is a diagram illustrating the circuit diagram of a mixing circuit 320c of the mixer 120c. Content that overlaps with FIGS. 7A and 7B will be omitted for the sake of clarity and brevity.

Referring to FIG. 7C, the mixer 120c may include the first filter 711 that is connected in series with the first power source 111, and the first filter 711 may reduce and/or prevent the RF signals from being interfered with by the non-sinusoidal wave signals, and the first capacitor 713 that is connected in series with the first power source 111, and the first capacitor 713 may reduce and/or prevent the RF signals from being interfered with by the DC signals. The mixer 120 may include the impedance matching circuit 715 connected in series with the first power source 111. Meanwhile, according to at least one example embodiment, the first capacitor 713 may not be included (e.g., may be omitted), but the example embodiments are not limited thereto.

According to at least one example embodiment, the mixer 120 may include the second filter 721 that is connected in series with the second power source 113, and the second filter 721 may reduce and/or prevent the non-sinusoidal wave signals from being interfered with by the RF signals, etc. The mixer 120 may include a third filter 731c that is connected in series with the third power source 115, and the third filter 731c may reduce and/or prevent the DC signals from being interfered with by the RF signals and/or the non-sinusoidal wave signals, etc. The second filter 721 may include an LPF that passes only the low-band part and a BSF that cancels only the frequency of a specific band, but is not limited thereto.

According to at least one example embodiment, the mixer 120 may include the second capacitor 723 that is connected to the first power source 111 and the second power source 113, and the second capacitor 723 may reduce and/or prevent the RF signal and/or the non-sinusoidal wave signal from being interfered with by the DC signal, etc. By the second capacitor 723, the RF signals and/or the non-sinusoidal wave signals may be reduced and/or prevented from being interfered with by the DC signals. The second capacitor 723 may be a block capacitor, but is not limited thereto.

In other words, the mixer 120c according to the at least one example embodiment illustrated in FIG. 7C may have an equivalent circuit structure that produces the same effect as the mixer 120a according to the at least one example embodiment illustrated in FIG. 7A and the mixer 120b according to the at least one example embodiment illustrated in FIG. 7B, but the example embodiments are not limited thereto.

If a unipolar signal with negative polarity is applied to the lower electrode 220 for plasma processing, electrons accumulate on the lower electrode 220, which cause a surface magnetic field to be formed so that the potential of the plasma near the lower electrode 220 may have a negative polarity (e.g., the lower electrode 220 may have a negative voltage, etc.). This is called potential drop. Only negative voltage may be applied to the surface of the substrate placed on the surface of the upper part of the ESC 210 due to the potential drop. In other words, the negative voltage corresponding to the peak-to-peak value of the non-sinusoidal wave signal may be applied to the substrate and/or a surface of the substrate. This may be called self-bias. In this situation, if a pattern is formed on the substrate and the etching process is performed, due to the potential drop, positive ions (or positive charges) may be attracted to the substrate, and the positive ions may accumulate at the etched area (in other words, the bottom surface of the pattern). An electric field may be formed on the bottom surface of the pattern due to these accumulated positive ions. The electric field formed in this way may attract negative ions inside the plasma, causing the etching direction of the plasma to deviate. For example, etching must be performed vertically according to the pattern formed on the substrate, but if the etching direction is misaligned, deflected, and/or is changed due to the electric field, defects may occur on the substrate, such as etching progressing at an angle, etc. Further, if a trench structure (e.g., a straight structure) is formed on the substrate, defects may occur in that etching is performed in a curved line instead of a straight line, etc. In order to resolve the defects, it is important to remove positive ions accumulated on the bottom surface of the substrate pattern, or in other words, neutralizing the polarity of the surface of the substrate is important, etc.

If the etching process is performed while a synthesized signal of an RF signal and a unipolar non-sinusoidal wave signal with negative polarity is applied to the lower electrode 220 of the substrate processing apparatus 10, a phenomenon may occur on the surface of the substrate where etching is performed sharply in areas that should be etched flat, which causes a sharp defect. As described above, if the first synthesized signal is applied to the lower electrode 220, only the negative voltage is applied to the substrate placed on the ESC 210, and positive ions accumulate at the etched area, in other words, the bottom surface of the pattern, and accordingly, the sharp defect may occur.

If the etching process is performed while a synthesized signal in which an RF signal, a unipolar non-sinusoidal wave signal with the negative polarity, and a DC signal with the positive polarity are synthesized is applied to the lower electrode 220 of the substrate processing apparatus 10, the sharp defect may not occur on the surface of the substrate. If the synthesized signal is applied to the lower electrode 220, by the positive voltage as well as the negative voltage being applied on the substrate mounted on the ESC 210, cations accumulated on the bottom surface of the substrate pattern are removed, or in other words, neutralized, and thus the sharp defect does not occur.

According to one or more example embodiments, instead of a unipolar signal with a negative polarity, a waveform with an adjusted DC voltage level is injected into the lower electrode 220 of the substrate processing apparatus 10, and consequently, equipment arcing may be reduced and/or prevented.

According to at least one example embodiment, the substrate processing apparatus 10 may include the processing chamber 200 including the ESC 210 supporting a substrate, and the lower electrode 220 inside the ESC 210, the first power source 111 that generates the RF signals, the second power source 113 to generate the non-sinusoidal wave signal, the third power source 115 that generates the DC signal, the mixer 120 that generates an output signal by mixing the RF signal, the non-sinusoidal wave signal and the DC signal, and provides the output signal to the lower electrode 220, and/or the processor 280 that controls the first power source 111, the second power source 113 and/or the third power source 115, etc., but the example embodiments are not limited thereto.

According to at least one example embodiment, the mixer 120 may include the first input port 311 configured to receive the RF signals from the first power source 111, the second input port 313 configured to receive the non-sinusoidal wave signal from the second power source 113, the third input port 315 configured to receive the DC signal from the third power source 115, the mixing circuit 320 configured to generate an output signal by mixing the RF signal, the non-sinusoidal wave signal and the DC signal, and/or the output port 330 configured to output the output signal generated from the mixing circuit 320, etc.

The substrate processing apparatus according to one or more of the above-described example embodiments may include a processor, a memory for storing and executing program data, a permanent storage such as a disk drive, and/or a user interface device such as a communication port, a touch panel, a key and/or a button that communicates with an external device. Methods implemented as software modules and/or algorithms may be stored in a non-transitory computer-readable recording medium as computer-readable codes or program instructions executable on the processor. Here, the non-transitory computer-readable recording medium includes a magnetic storage medium (for example, ROMs, RAMs, floppy disks and hard disks) and an optically readable medium (for example, CD-ROMs, DVDs, Blu-ray disks, etc.). The computer-readable code may be distributed among network-connected computer systems, so that the computer-readable codes may be stored and executed in a distributed manner. The medium may be readable by a computer, stored in a memory, and executed on a processer, etc.

One or more of the example embodiments may be represented by functional block elements and various processing steps. The functional blocks may be implemented in any number of hardware and/or software configurations that perform specific functions. For example, at least one example embodiment may adopt integrated circuit configurations, such as memory, processing, logic, and/or look-up tables, etc., that may execute various functions by the control of one or more microprocessors or other control devices. Similar to that elements may be implemented as software programming and/or software elements, one or more of the example embodiments may be implemented in a programming or scripting language such as C, C++, Java, assembler, etc., including various algorithms implemented as a combination of data structures, processes, routines, and/or other programming constructs. Functional aspects may be implemented in an algorithm running on one or more processors. Further, one or more of the example embodiments may adopt the existing art for electronic environment setting, signal processing, and/or data processing. Terms such as “mechanism,” “element,” “means” and “configuration” may be used broadly and are not limited to mechanical and physical elements. The terms may include the meaning of a series of routines of software executed using a processor or the like.

The above example embodiments are merely examples and other example embodiments may be implemented within the scope of the claims described below.

What is claimed is:

1. A plasma control apparatus comprising:
a first power source configured to generate an RF signal;
a second power source configured to generate a non-sinusoidal wave signal;
a third power source configured to generate a direct current (DC) signal; and
a mixer configured to,
generate an output signal based on the RF signal, the non-sinusoidal wave signal, and the DC signal, and
provide the output signal to a lower electrode inside an electrostatic chuck (ESC) of a processing chamber.

2. The plasma control apparatus of claim 1, wherein the mixer comprises:
a first filter that is connected in series with the first power source, the first filter configured to reduce interference between the RF signal and the non-sinusoidal wave signal; and
a first capacitor that is connected in series with the first power source, the first capacitor configured to reduce interference between the RF signal and the DC signal.

3. The plasma control apparatus of claim 2, wherein the mixer further comprises:
a second filter that is connected in series with the second power source, the second filter configured to reduce interference between the non-sinusoidal wave signal and the RF signal; and
a second capacitor that is connected in series with the second power source, the second capacitor configured to reduce interference between the non-sinusoidal wave signal and the DC signal.

4. The plasma control apparatus of claim 3, wherein the mixer further comprises:
a third filter that is connected in series with the third power source, the third filter configured to reduce interference between the DC signal and the non-sinusoidal wave signal.

5. The plasma control apparatus of claim 2, wherein the mixer further comprises:
a second capacitor that is connected in series with the second power source, the second capacitor configured to reduce interference between the non-sinusoidal wave signal and the DC signal; and
a third filter that is connected in series with the third power source, the third filter configured to reduce interference between the DC signal, the RF signal, and the non-sinusoidal wave signal.

6. The plasma control apparatus of claim 5, wherein the mixer further comprises:
a second filter that is connected to the second power source and the third power source, the second filter configured to reduce interference between the non-sinusoidal wave signal, the DC signal, and the RF signal.

7. The plasma control apparatus of claim 2, wherein the mixer further comprises:
a second filter that is connected in series with the second power source, the second filter configured to reduce interference between the non-sinusoidal wave signal and the RF signal; and
a third filter connected in series with the third power source, the third filter configured to reduce interference between the DC signal, the RF signal, and the non-sinusoidal wave signal.

8. The plasma control apparatus of claim 7, further comprising:
a second capacitor that is connected to the first power source and the second power source, the second capacitor configured to reduce interference between the RF signal, the non-sinusoidal wave signal, and the DC signal.

9. The plasma control apparatus of claim 2, wherein the mixer further comprises:
an impedance matching circuit that is connected in series with the first power source.

10. The plasma control apparatus of claim 3, wherein
the first filter comprises a band pass filter; and
the second filter comprises a low pass filter and a band stop filter.

11. The plasma control apparatus of claim 4, wherein the third filter comprises:
a low pass filter (LPF).

12. The plasma control apparatus of claim 3, wherein the first capacitor and the second capacitor are block capacitors.

13. The plasma control apparatus of claim 1, wherein
the second power source is configured to generate the non-sinusoidal wave signal as a unipolar signal with a voltage of a first polarity; and
the third power source is configured to generate the DC signal as a DC signal with a voltage of a second polarity, the second polarity being opposite to the first polarity.

14. The plasma control apparatus of claim 1, wherein
the first power source is configured to generate the RF signal as a sinusoidal wave signal with a high frequency; and
the second power source is configured to generate the non-sinusoidal wave signal as a square wave signal with a low frequency pulse form.

15. The plasma control apparatus of claim 14, wherein
the high frequency corresponds to a frequency that is suitable for generating plasma around a substrate on the ESC; and
the low frequency corresponds to a frequency that is suitable for generating a pattern on the substrate.

16. The plasma control apparatus of claim 1, wherein the mixer is configured to:
generate the output signal as a bipolar signal having a pulse shape over time.

17. The plasma control apparatus of claim 16, wherein the mixer is configured to:
apply the bipolar output signal to the lower electrode, the bipolar output signal causing a voltage to be applied to a substrate on the ESC.

18. The plasma control apparatus of claim 1, wherein third power source is configured to:
generate the DC signal, the DC signal having a voltage value that is between 10% and 20% of a peak-to-peak value of the non-sinusoidal wave signal.

19. The plasma control apparatus of claim 1, wherein
the ESC is in an internal space of the processing chamber; and
the ESC is configured to support a substrate.

20. The plasma control apparatus of claim 1, wherein
the lower electrode is inside the ESC; and
the lower electrode is configured to generate plasma by activating a reaction gas in an internal space of the processing chamber based on the output signal.
